(19) United States
(12) Patent Application Publication
(10) Pub. No.: US 2021/0368618 A1
(43) Pub. Date: Nov. 25, 2021

(54) CIRCUIT ASSEMBLY AND ELECTRICAL JUNCTION BOX

(71) Applicant: Sumitomo Wiring Systems, Ltd., Yokkaichi-shi, Mie (JP)

(72) Inventors: Jun Ikeda, Yokkaichi-shi, Mie (JP); Yoshikazu Sasaki, Yokkaichi-shi, Mie (JP); Junya Aichi, Yokkaichi-shi, Mie (JP)

(21) Appl. No.: 17/280,587

(22) PCT Filed: Oct. 10, 2019
(86) PCT No.: PCT/JP2019/039990

§ 371 Date: Mar. 26, 2021

(30) Foreign Application Priority Data
Oct. 16, 2018 (JP) 2018-195245

(51) Int. Cl. H05K 1/02; H05K 7/20; H01L 25/11

(52) U.S. Cl. CPC H05K 1/0272; H02G 3/08; H01L 25/115; H05K 7/20409

(57) ABSTRACT

A circuit assembly that includes a plurality of FETs that include source terminals and gate terminals. The circuit assembly includes a substrate portion to which the source terminals and the gate terminals are connected, and through-holes that are formed in the substrate portion for each FET and pass through the substrate portion in the thickness direction thereof.

### CROSS-REFERENCE TO RELATED APPLICATIONS

This application is the U.S. national stage of PCT/JP2019/039990 filed on Oct. 10, 2019, which claims priority of Japanese Patent Application No. JP 2018-195245 filed on Oct. 16, 2018, the contents of which are incorporated herein.

### TECHNICAL FIELD

The present disclosure relates to a circuit assembly and electrical junction box that include a plurality of semiconductor elements.

### BACKGROUND

Currently, circuit assemblies are commonly known on which electrically conductive members (known as bus bars or the like) are mounted, and the electrically conductive members constitute circuitry for conducting a relatively large current.

On the other hand, JP 2018-063982A discloses an electronic device in which holes are formed in the housing thereof to promptly allow heat produced by electrical components in the housing to be expelled to the outside thereof, and to cool the electrical components by drawing air into the housing.

In circuit assemblies like those described above, a large amount of heat is produced in the electrically conductive members in addition to the electronic components because a large current flows through the electronic components such as semiconductor elements. Such generated heat can cause the electronic components to malfunction, and can also cause the surrounding electronic components and the like to take secondary thermal damage.

With the electrical device in JP 2018-063982A, even though holes are formed in the housing to address the problem described above, there are concerns that dust, water, or the like may enter the housing from the outside due to the holes being formed in the housing. With the electronic device in JP 2018-063982A, filters are separately provided to prevent such substances from entering the holes of the housing, but this results in problems in which the structure of the electronic device becomes complex and the production costs increase.

An object of the present disclosure is to provide a circuit assembly and electrical junction box with which it is possible to increase the ability to dissipate heat produced by semiconductor elements with a simple structure.

### SUMMARY

A circuit assembly according to an aspect of the present disclosure includes a plurality of semiconductor elements that include first terminals and second terminals, the circuit assembly including: a substrate portion to which the first terminals and the second terminals are connected; and through-holes that are formed in the substrate portion for each semiconductor element, and pass through the substrate portion in the thickness direction thereof.

An electrical junction box according to another aspect of the present disclosure includes: the circuit assembly described above; a hollow dissipation portion that covers the plurality of semiconductor elements; and thermally conductive members that are interposed between the semiconductor elements and the hollow dissipation portion.

### Advantageous Effects of Disclosure

According to aspects of the present disclosure, it is possible to increase the ability to dissipate heat produced by semiconductor elements with a simple structure.

### BRIEF DESCRIPTION OF DRAWINGS

FIG. 1 is a front view of an electrical device according to a first embodiment.

FIG. 2 is an exploded view of the electrical device according to the first embodiment.

FIG. 3 is a schematic diagram of a circuit assembly of the electrical device according to the first embodiment, as seen from below.

FIG. 4 is an enlarged view that enlarges and shows the portion of FIG. 3 that is surrounded by the dashed line.

FIG. 5 is a schematic longitudinal sectional view taken along line V-V in FIG. 4.

FIG. 6 is a schematic longitudinal sectional view taken along line VI-VI in FIG. 4.

FIG. 7 is a partial longitudinal sectional view showing the relationship between FETs and a hollow portion in the electrical device according to a second embodiment.

### DETAILED DESCRIPTION OF PREFERRED EMBODIMENTS

First, embodiments of the present disclosure will be listed and described. Also, at least portions of the embodiments described below can be freely combined.

A circuit assembly according to an aspect of the present disclosure includes a plurality of semiconductor elements that include first terminals and second terminals, the circuit assembly including: a substrate portion to which the first terminals and the second terminals are connected; and through-holes that are formed in the substrate portion for each semiconductor element, and pass through the substrate portion in the thickness direction thereof.

With this aspect, the through-holes that pass through the substrate portion in the thickness direction thereof are formed in the substrate portion for each semiconductor element. Accordingly, if heat is produced by the semiconductor elements, a dissipating effect is exhibited in which the heat can move from one surface side of the substrate portion to another surface side of the substrate portion via the through-holes.

The circuit assembly according to another aspect of the present disclosure is configured such that a current that is to flow through the second terminals is smaller than a current that is to flow through the first terminals, the circuit assembly further including: a conductive plate that is connected to the first terminals of the plurality of semiconductor elements; and conductive members that are connected to the second terminals of the semiconductor elements, where the number of the conductive members is the same as the number of the plurality of semiconductor elements, wherein the through-holes are formed in the vicinity of the second terminals.

With this aspect, the through-holes are formed in the vicinity of the conductive member to which the second terminals are connected, the second terminals having a current flow therethrough that is smaller than the current that flows through the first terminals. It is possible to prevent an increase in resistance due to the through-holes because the through-holes are formed in the vicinity of the second terminals (conductive member) through which the smaller current flows.

The circuit assembly according another aspect of the present disclosure is configured such that the conductive plate includes recessed portions in which one end portion of the conductive members is arranged, the resin portion is formed between an edge of the recessed portions and the one end portion of the conductive members, and the through-holes are formed in the resin portion.

With this aspect, one end portion of the conductive member is arranged sandwiching the resin portion on the inner side of the recessed portion of the conductive plate, and the through-holes are formed in the resin portion. In this way, the through-holes are formed in the resin portion and therefore it is possible to prevent an increase in resistance due to the through-holes being formed in the conductive member or the conductive plate, and the through-hole can be easily formed.

An electrical junction box according to another aspect of the present disclosure includes: the circuit assembly described above; a hollow dissipation portion that covers the plurality of semiconductor elements; and thermally conductive members that are interposed between the semiconductor elements and the hollow dissipation portion.

With this aspect, a thermally conductive member is interposed between the semiconductor elements and the hollow dissipation portion. The thermally conductive member is in contact with an inner side surface of the semiconductor elements and the hollow dissipation portion, and heat that is produced by the semiconductor elements is quickly transmitted to the hollow dissipation portion. Accordingly, heat produced by the semiconductor elements can be effectively dissipated.

The electrical junction box according another aspect of the present disclosure further includes a dissipation fin that is provided on an outer side of the hollow dissipation portion, and acquires and dissipates heat from the hollow dissipation portion.

With this aspect, the dissipation fin is provided on an outer side of the hollow dissipation portion. Accordingly, the thermally conductive member transmits the heat that is produced by the semiconductor elements to the hollow dissipation portion, and the heat that is transmitted to the hollow dissipation portion is air-cooled via the dissipation fin. Accordingly, heat produced by the semiconductor elements can be effectively dissipated.

The following specifically describes the present disclosure based on drawings that show embodiments thereof. A circuit assembly and electrical junction box according to an embodiment of the present disclosure will be described below with reference to the drawings. Note that the present disclosure is not limited to these illustrative examples and is defined by the claims, and all changes which come within the meaning and range of equivalency of the claims are intended to be embraced therein.

### First Embodiment

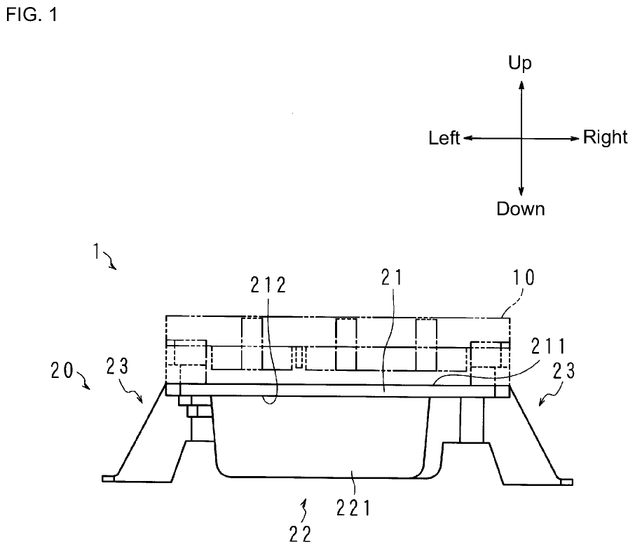

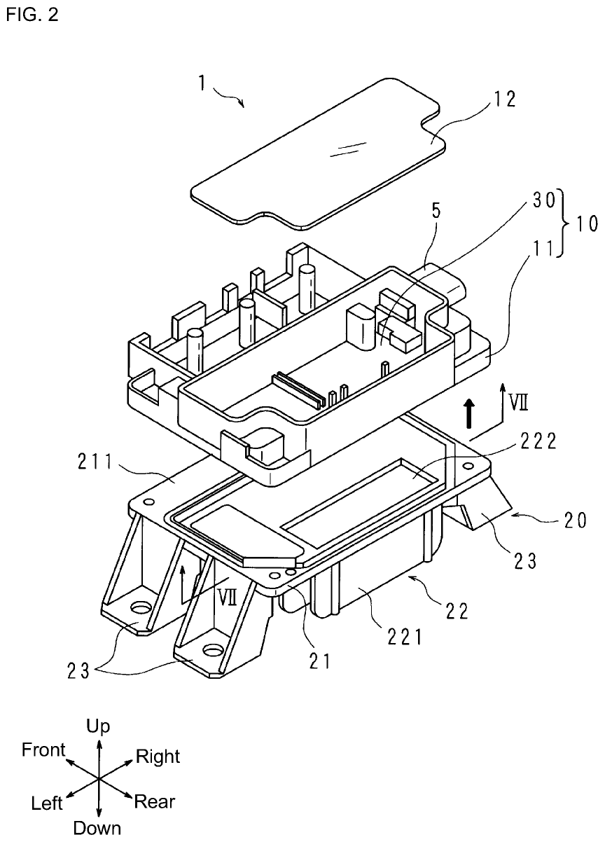

The following lists and describes examples of an electrical device (electrical junction box) that includes a circuit assembly according to the first embodiment. FIG. 1 is a front view of an electrical device 1 according to a first embodiment, and FIG. 2 is an exploded view of the electrical device 1 according to the first embodiment.

The electrical device 1 is an electrical junction box that is provided on a power supply path between a power source such as a battery provided in a vehicle and a load constituted by an automotive electrical device, such as a lamp or a wiper, a motor, or the like. The electrical device 1 can be used as the electronic components of a DC-DC converter, inverter, or the like.

In the first embodiment, for the sake of convenience, the forward-rearward, left-right, and up-down directions in FIGS. 1 and 2 respectively define “front”, “rear”, “left”, “right”, “top”, and “bottom” of the electrical device 1. The following description uses the forward-rearward, left-right, and up-down directions as defined above to describe the configuration of the electrical device 1.

The electrical device 1 includes a circuit assembly 10, a circuit board 12 that has a circuit pattern, and a support member 20 that supports the circuit assembly 10.

The circuit assembly 10 includes bus bars that constitute a power circuit, and electronic components that are mounted on the circuit board and the bus bar. The electronic components are appropriately mounted in accordance with the purpose of the electrical device 1, and include switching elements such as FETs (Field Effect Transistors), resistors, coils, capacitors, and the like.

The support member 20 includes a base portion 21 that includes a support surface 211 whose upper surface supports the circuit assembly 10, a dissipation portion 22 that is provided on a surface (lower surface 212) that is on the side of the base portion 21 that is opposite to the support surface 211 side, and a plurality of leg portions 23 that sandwich the dissipation portion 22 and are provided on the left and right ends of the base portion 21. The base portion 21, the dissipation portion 22, and the leg portions 23 that are included in the support member 20 may be formed as a single body with a die cast using a metal material such as aluminum or an aluminum alloy.

The base portion 21 is a rectangular flat plate member having an appropriate thickness. The support surface 211 of the base portion 21 has a circuit assembly 10 fixed thereto with a known method such as bonding, screwing, or soldering.

The dissipation portion 22 includes a plurality of dissipation fins 221 that protrude downward from the lower surface 212 of the base portion 21, and dissipate heat produced by the circuit assembly 10 to the outside thereof. The plurality of dissipation fins 221 extend in the left-right direction and are provided in parallel with spaces therebetween in the front-rear direction. Also, the dissipation portion 22 includes a hollow portion 222 (hollow dissipation portion) that covers FETs 13, which will be described later, and the dissipation fins 221 are provided on an outer side of the hollow portion 222.

The leg portions 23 are provided on the left and right ends of the base portion 21. The right and left sides of the base portion 21 may be provided with one of the leg portions 23 each, or a plurality of the leg portions 23 each.

The circuit board 12 includes a substantially rectangular insulating substrate, for example. The insulating substrate has a control circuit (not shown) mounted thereto that includes electronic components such as resistors, coils, capacitor, and diodes, and the insulating substrate has a circuit pattern formed thereon that electrically connects the electronic components. The control circuit of the circuit board 12 gives an on/off signal to a power circuit 30, which will be described later, and controls the power circuit 30. Note that the circuit board 12 and the power circuit 30 are accommodated in an accommodation portion 11.

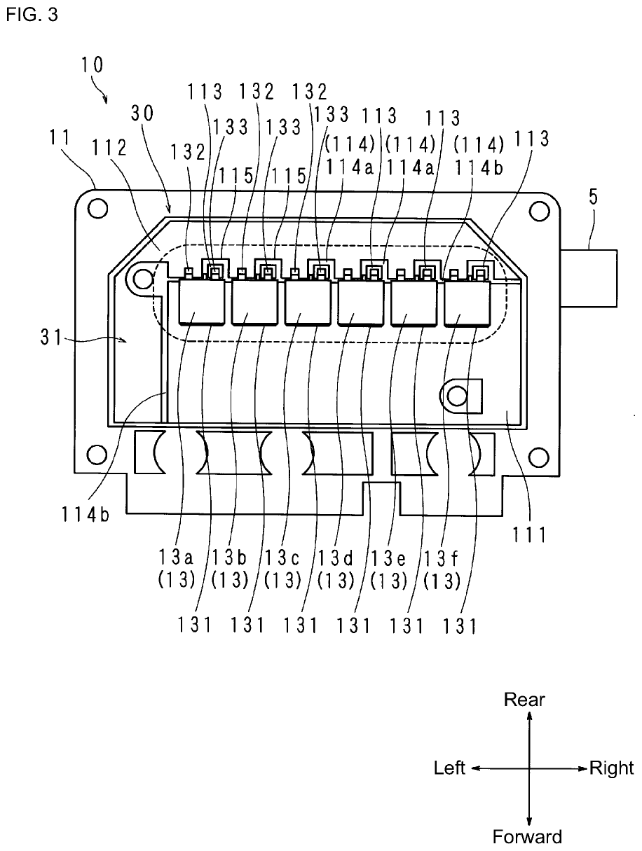

FIG. 3 is a schematic diagram of the circuit assembly 10 of the electrical device 1 according to the first embodiment, as seen from below. That is, FIG. 3 is a diagram showing the circuit assembly 10 if viewed in the direction of the arrow in FIG. 2.

The circuit assembly 10 includes the power circuit 30. The power circuit 30 includes bus bars 111 to 113, and semiconductor switch elements 13 (semiconductor element) that switch between conduction and non-conduction based on a control signal when the control signal is input from the circuit board 12.

The semiconductor switch elements 13 may be FETs (or more specifically, surface-mounted type power MOSFETs) for example, and are mounted to the lower surface side of the bus bars 111 to 113. Other than the semiconductor switch elements 13 (referred to as the FETs 13 below), electronic components such as Zener diodes may also be mounted to the lower surface side of the bus bars 111 and 112.

The FETs 13 may include, for example, drain terminals 131 on a main surface of their element bodies, and the drain terminals 131 poke out from one side surface side of the element bodies. Also, the FETs 13 include source terminals 132 (first terminals) and gate terminals 133 (second terminals) on another side surface that opposes that one side surface of the element bodies. FIG. 3 shows an example in which six FETs 13a to 13f are mounted on the power circuit 30, but there is no limitation thereto. The FETs 13a to 13f are also referred to as the FETs 13 in the following description.

The drain terminals 131 of the FETs 13 are solder-connected to the bus bar 111. The bus bar 111 is referred to as a drain bus bar 111 in the following description. Also, the source terminals 132 of the FETs 13 are solder-connected to a bus bar 112 (conductive plate). The bus bar 112 is also referred to as a source bus bar 112 in the following description.

The drain bus bar 111 and the source bus bar 112 are conductive plate members formed from a metal material such as copper or a copper alloy.

On the other hand, the gate terminals 133 of the FETs 13 allow current to flow therethrough that is smaller than current that flows through the source terminals 132 and the drain terminals 131, and are solder-connected to the bus bar 113 (conductive member). The bus bars 113 are also referred to as gate bus bars 113 in the following description. The gate bus bars 113 are conductive members formed from a metal material such as copper or a copper alloy.

A resin portion 114 made of an insulating resin material is interposed between the drain bus bar 111, the source bus bar 112, and the gate bus bars 113, and the gate bus bars 113 are formed as a single piece with the resin portion 114 and constitutes a substrate portion 31.

The substrate portion 31 is substantially rectangular in the up-down direction, and has a flat lower side surface. The FETs 13a to 13f are mounted to the lower side surface of the substrate portion 31. The FETs 13a to 13f are provided in parallel with each other along the length direction of the substrate portion 31 (the left-right direction).

The resin portion 114 is produced with insert molding using an insulating resin material such as phenol resin or glass epoxy resin. The resin portion 114 and the accommodation portion 11 may be formed as a single body with the same process, for example. Also, the accommodation portion 11 supports the peripheral edge portion of the circuit board 12 from the lower surface side thereof with ribs (not shown) that are formed on the inner surface of the peripheral walls of the accommodation portion 11.

The drain bus bar 111, the source bus bar 112, and the gate bus bars 113 engage with the resin portion 114, and thereby form a single body. Also, a portion of the resin portion 114 is arranged in the space between the drain bus bar 111, the source bus bar 112, and the gate bus bars 113, thus providing insulation between the bus bars.

A tubular housing 5 that protects an outer side end portion of a connector terminal (not shown) is attached to an outer side of the right side wall of the accommodation portion 11.

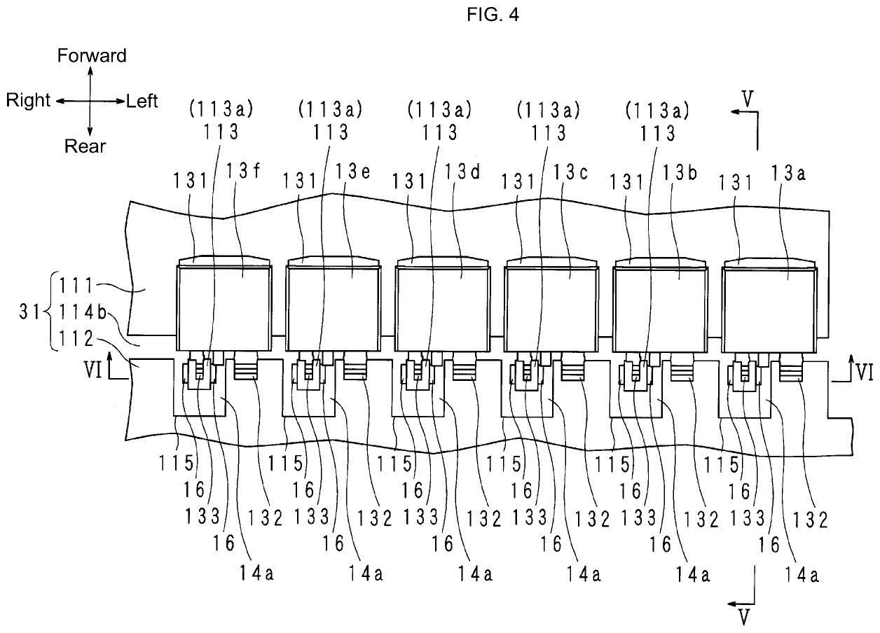

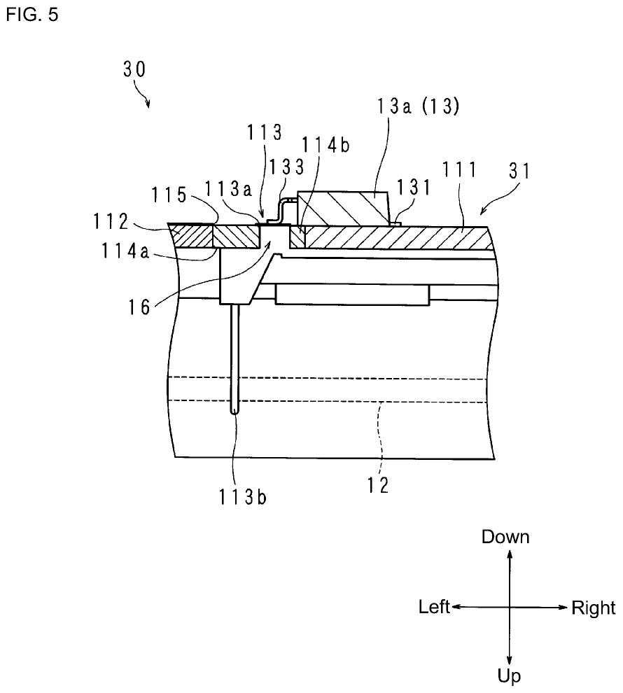

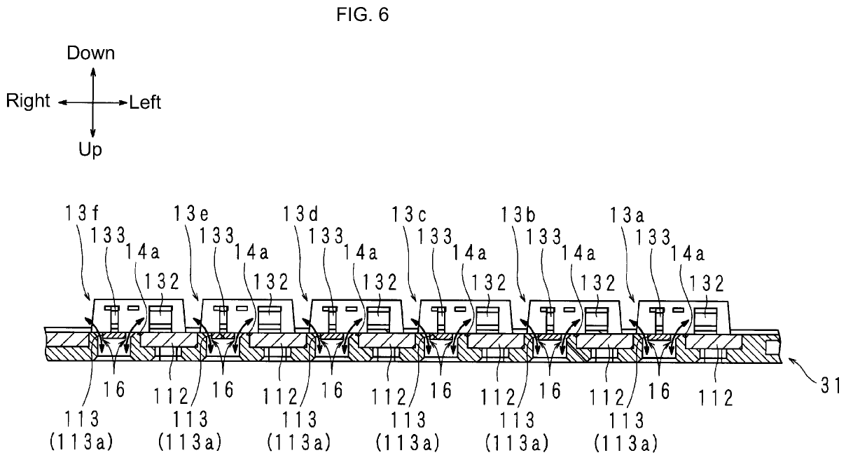

FIG. 4 is an enlarged view that enlarges and shows the portion of FIG. 3 that is surrounded by the dashed line, FIG. 5 is a schematic longitudinal sectional view taken along line V-V in FIG. 4, and FIG. 6 is a schematic longitudinal sectional view taken along line VI-VI in FIG. 4.

The drain bus bar 111 is larger than the source bus bar 112 and the gate bus bars 113, and has rectangular plate shape. That is to say, the drain bus bar 111 has the largest exposed surface area in the substrate portion 31 and takes up a large portion on the front side thereof. Also, FETs 13a to 13f are fixed to the drain bus bar 111 by each of the drain terminals 131 being soldered to the drain bus bar 111.

A resin portion 114b of the resin portion 114 is interposed between the drain bus bar 111 and source bus bar 112. That is, the drain bus bar 111 and the source bus bar 112 sandwich the resin portion 114b from opposite sides. On the drain bus bar 111, the FETs 13a to 13f are provided in parallel to each other along a side edge portion opposing the source bus bar 112, and are arranged such that the source terminals 132 and the gate terminals 133 face the source bus bar 112.

The source bus bar 112 has comb-shaped projections formed in the side thereof that faces the side of the drain bus bar 111 to which the FETs 13a to 13f are fixed. That is, a plurality of recessed portions 115 are formed in the side edge portion of the source bus bar 112. The recessed portions 115 are formed in positions that correspond to the gate terminals 133 of the corresponding FETs 13a to 13f.

The source bus bar 112 is smaller than the drain bus bar 111 and has a substantially trapezoidal plate shape. The source terminals 132 of the FETs 13a to 13f are soldered to the side edge portion of the source bus bar 112, not including the recessed portions 115.

The terminal connection portions 113a of the gate bus bars 113, which will be described later, are arranged in the recessed portions 115, spaced apart from the edges of the recessed portions 115. Also, a resin portion 114a of the resin portion 114 is interposed between the edges of the recessed portions 115 and the terminal connection portions 113a of the gate bus bars 113. That is, the terminal connection portions 113a of the gate bus bars 113 are surrounded by the resin portion 114a, and the gate bus bars 113 and the source bus bar 112 are thereby insulated.

The gate terminals 133 of the FETs 13a to 13f are connected to the gate bus bars 113. More specifically, the gate bus bars 113 are bent into an L-shape, include the terminal connection portions 113a soldered to the gate terminals 133 at a lower side end, and include substrate connection portions 113b that are connected to the circuit board 12 at another, upper side end (see FIG. 5). The substrate connection portions 113b of the gate bus bars 113 have fin shapes that are finer at one end than the terminal connection portions 113a are.

The terminal connection portions 113a are rectangular in a planar view thereof, and are exposed from the lower side surface of the substrate portion 31. The terminal connection portions 113a are provided so as to be flush with the source bus bar 112 and the resin portion 114a. As described above, the gate terminals 133 of the FETs 13a to 13f are soldered to the terminal connection portions 113a, and the terminal connection portions 113a are surrounded by the resin portion 114a.

In the vicinity of the gate terminals 133 (the terminal connection portions 113a) in the resin portion 114a, through-holes 16 are formed passing through the resin portion 114a (the substrate portion 31) in the thickness direction thereof, that is to say the up-down direction. For example, the through-holes 16 may be formed in the border between the terminal connection portions 113a and the resin portion 114a. The through-holes 16 are formed on two sides of the terminal connection portions 113a in the left-right direction. In the present embodiment, a case is described in which through-holes 16 are provided in two places, but there is no limitation thereto, and the through-holes 16 may also be provided in three or more places.

The FETs 13a to 13f that are provided in parallel on the lower surface of the substrate portion 31 are covered by the hollow portion 222 of the dissipation portion 22. If the FETs 13a to 13f produce heat, the heat is conducted to the inside of the hollow portion 222, and is air-cooled via the plurality of dissipation fins 221.

Furthermore, as described above, the circuit assembly 10 according to the present embodiment includes the through-holes 16 formed in the substrate portion 31 for each of the FETs 13a to 13f. Thus, air can easily pass between the upper side of the substrate portion 31 and the lower side of the substrate portion 31. That is, in the circuit assembly 10 according to the present embodiment, air at the bottom side of the substrate portion 31 on which the FETs 13a to 13f are mounted, which are heat-producing bodies, can freely move towards the upper side of the substrate portion 31 via the through-holes 16 (see the arrow in FIG. 6). Accordingly, if heat is produced by the FETs 13a to 13f, hot air that contains the heat does not become trapped in the hollow portion 222 and moves to the upper side of the substrate portion 31 via the through-holes 16, and therefore a heat dissipating effect is exhibited.

Also, in the present embodiment, the through-holes 16 are formed in the vicinity of the gate terminals 133 (the terminal connection portions 113a). That is, the through-holes 16 are formed at each of the FETs 13a to 13f and also in the vicinity of the heat sources of the FETs 13a to 13f, and therefore heat can be more efficiently dissipated.

With the circuit assembly 10 according to the present embodiment, heat produced by the FETs 13a to 13f is dissipated with use of the through-holes 16 in addition to the dissipation fins 221, and therefore heat can be more reliably dissipated. Accordingly, it is possible to prevent malfunctions, damage, and the like caused to the FETs 13a to 13f by heat that is produced by the FETs 13a to 13f, and it is possible to prevent secondary thermal damage being caused to electronic components and the like in the periphery of the FETs 13a to 13f.

In the present embodiment, the through-holes 16 are formed in the resin portion 114a in the vicinity of the gate terminals 133 (the terminal connection portions 113a). Accordingly, the through-holes 16 can be formed more easily than forming the through-holes 16 in the terminal connection portions 113a.

However, the circuit assembly 10 according to the present embodiment is not limited thereto. The through-holes 16 may also be formed in any of the drain bus bar 111, the source bus bar 112, and the gate bus bars 113, as long as the through-holes 16 are in the vicinity of the FETs 13a to 13f.

If the through-holes 16 are formed in any of the drain bus bar 111, the source bus bar 112, or the gate bus bars 113, there is concern that the resistance to current will increase in the bus bars. Also, the resistance is proportional to the amount of current flowing. On the other hand, as described above, the current that flows through the gate terminal 133 is smaller than the current that flows through the drain terminals 131 and the source terminals 132. Accordingly, it is desirable that the through-holes 16 are formed in the vicinity of the gate bus bars 113 or the gate terminals 133 through which a current flows that is smaller than current that flows through the drain bus bar 111 and the source bus bar 112.

Furthermore, as described above, there is concern that resistance will increase if the through-holes 16 are formed in any of the drain bus bar 111, the source bus bar 112, and the gate bus bars 113, and therefore, as with the present embodiment, it is desirable that the through-holes 16 are provided in the resin portion 114.

### Second Embodiment

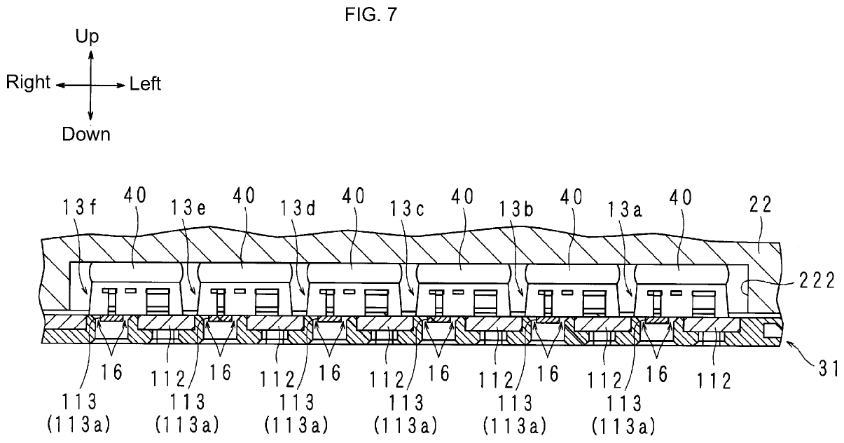

FIG. 7 is a partial longitudinal sectional view of the FETs 13a to 13f and the hollow portion 222 in the electrical device 1 according to a second embodiment.

As shown in FIG. 7, the FETs 13a to 13f are mounted to the lower surface of the substrate portion 31, and the FETs 13a to 13f are covered by the hollow portion 222 of the dissipation portion 22. Furthermore, in the present embodiment, a thermally conductive member 40 is interposed between the FETs 13a to 13f and the inner surfaces of the hollow portion 222. The thermally conductive member 40 may be a grease having excellent thermal conductivity, a thermally conductive sheet, or the like. The thermally conductive member 40 is in contact with the lower surfaces of the FETs 13a to 13f and the inner surface of the hollow portion 222, and heat that is produced by the FETs 13a to 13f is transmitted to the hollow portion 222.

In this way, in the electrical device 1 according to the present embodiment, if heat is produced in the FETs 13a to 13f, the heat can be quickly conducted to the hollow portion 222 via the thermally conductive member 40. Next, the dissipation fins 221 acquire the heat from the hollow portion 222 and are air cooled. Accordingly, heat that is produced by the FETs 13a to 13f can be more effectively dissipated.

Portions of the second embodiment that are the same as those in the first embodiment are denoted with the same reference numerals and detailed descriptions thereof are omitted.

The presently disclosed embodiments should be considered illustrative in all respects and not restrictive. Note that the present disclosure is defined not by the meanings of the foregoing descriptions, but is defined by the claims, and all changes which come within the meaning and range of equivalency of the claims are intended to be embraced therein.

1. A circuit assembly that includes a plurality of semiconductor elements that include first terminals and second terminals, the circuit assembly comprising:
a substrate portion to which the first terminals and the second terminals are connected; and
through-holes that are formed in the substrate portion for each semiconductor element, pass through the substrate portion in the thickness direction thereof, and allow air to move between two surface sides of the substrate portion.

2. The circuit assembly according to claim 1, wherein:
a current that is to flow through the second terminals is smaller than a current that is to flow through the first terminals, the circuit assembly further comprising:
a conductive plate that is connected to the first terminals of the plurality of semiconductor elements; and
conductive members that are connected to the second terminals of the semiconductor elements, where the number of the conductive members is the same as the number of the plurality of semiconductor elements,
wherein the through-holes are formed in the vicinity of the second terminals.

3. The circuit assembly according to claim 2, wherein:
the conductive plate includes recessed portions in which one end portion of the conductive members is arranged,
the resin portion is formed between an edge of the recessed portions and the one end portion of the conductive members, and
the through-holes are formed in the resin portion.

4. An electrical junction box, comprising:
the circuit assembly according to claim 1;
a hollow dissipation portion that covers the plurality of semiconductor elements; and
thermally conductive members that are interposed between the semiconductor elements and the hollow dissipation portion.

5. The electrical junction box according to claim 4, further comprising a dissipation fin that is provided on an outer side of the hollow dissipation portion, and acquires and dissipates heat from the hollow dissipation portion.

6. The electrical junction box according to claim 4, wherein:
a current that is to flow through the second terminals is smaller than a current that is to flow through the first terminals, the circuit assembly further comprising:
a conductive plate that is connected to the first terminals of the plurality of semiconductor elements; and
conductive members that are connected to the second terminals of the semiconductor elements, where the number of the conductive members is the same as the number of the plurality of semiconductor elements,
wherein the through-holes are formed in the vicinity of the second terminals.

7. The electrical junction box according to claim 4, wherein:
the conductive plate includes recessed portions in which one end portion of the conductive members is arranged,
the resin portion is formed between an edge of the recessed portions and the one end portion of the conductive members, and
the through-holes are formed in the resin portion.
